(19) United States
(12) Patent Application Publication
(10) Pub. No.: US 2025/0301712 A1
(43) Pub. Date: Sep. 25, 2025

(54) SEMICONDUCTOR DEVICE AND MANUFACTURING METHOD THEREOF

(71) Applicant: NANYA TECHNOLOGY CORPORATION, New Taipei city (TW)

(72) Inventor: Yu Hua LIU, New Taipei City (TW)

(21) Appl. No.: 18/611,773

(22) Filed: Mar. 21, 2024

(51) Int. Cl. H01L 29/78; H01L 29/66

(52) U.S. Cl. CPC H10D 30/701; H10D 30/0415

(57) ABSTRACT

A semiconductor device includes a substrate, a gate dielectric, a dipole layer, a gate, a source region, and a drain region. The gate dielectric layer is over the substrate. The dipole layer is over the gate dielectric layer, in which the dipole layer is an oxygen-containing layer, and a width of the dipole layer is less than a width of the gate dielectric layer. The gate is over the dipole layer and the gate dielectric layer. The source region is in the substrate. The drain region is in the substrate, in which the source region and the drain region are at opposite sides of the gate dielectric layer.

### BACKGROUND

### Field of Disclosure

The present disclosure relates to a semiconductor device and a manufacturing method thereof.

### Description of Related Art

In traditional planar metal oxide semiconductor field effect transistor (MOSFET), the saturation current is determined by the inversion charge density. So if the inversion charge density can be increased, the saturation current can be also enlarged. The common method for increasing the inversion charge density is decreasing the threshold voltage by modulating the implant condition and thinning the gate oxide thickness. However, there will be the side effects of enlarged off-state current and gate leakage current. For example, it is more difficult to precisely control the implant region profile in the devices, leading to the unacceptable off-state leakage current. The thinner gate oxide may also lead to larger gate leakage.

### SUMMARY

Some embodiments of the present disclosure provide a semiconductor device including a substrate, a gate dielectric, a dipole layer, a gate, a source region, and a drain region. The gate dielectric layer is over the substrate. The dipole layer is over the gate dielectric layer, in which the dipole layer is an oxygen-containing layer, and a width of the dipole layer is less than a width of the gate dielectric layer. The gate is over the dipole layer and the gate dielectric layer. The source region is in the substrate. The drain region is in the substrate, in which the source region and the drain region are at opposite sides of the gate dielectric layer.

In some embodiments, the sidewall of the dipole layer near the source region is aligned with a sidewall of the gate dielectric layer near the source region.

In some embodiments, a sidewall of the dipole layer near the drain region is shifted laterally from a sidewall of the gate dielectric layer near the drain region.

In some embodiments, the semiconductor device further includes a high-k gate dielectric layer between the gate dielectric layer and the dipole layer, in which a dielectric constant of the high-k gate dielectric layer is higher than a dielectric constant of the gate dielectric layer.

In some embodiments, the high-k gate dielectric layer is in contact with the gate.

In some embodiments, the width of the dipole layer is less than a width of the high-k gate dielectric layer.

In some embodiments, the sidewall of the dipole layer near the source region is aligned with a sidewall of the high-k gate dielectric layer near the source region.

In some embodiments, a sidewall of the dipole layer near the drain region is shifted laterally from a sidewall of the high-k gate dielectric layer near the drain region.

In some embodiments, the sidewall of the dipole layer near the drain region is aligned with a sidewall of the gate dielectric layer near the drain region.

In some embodiments, a sidewall of the dipole layer near the source region is shifted laterally from a sidewall of the gate dielectric layer near the source region.

Some embodiments of the present disclosure provides a manufacturing method of a semiconductor device including forming a gate dielectric layer over a substrate, forming a dipole layer over the gate dielectric layer, in which the dipole layer covers a portion of the gate dielectric layer, forming a gate over the dipole layer and the gate dielectric layer, and forming a source region and a drain region in the substrate, in which the source region and the drain region are at opposite sides of the gate dielectric layer.

In some embodiments, after forming the source region and the drain region, the sidewall of the dipole layer near the source region is aligned with a sidewall of the gate dielectric layer near the source region.

In some embodiments, after forming the source region and the drain region, the sidewall of the dipole layer near the drain region is shifted laterally from a sidewall of the gate dielectric layer near the drain region.

In some embodiments, after forming the source region and the drain region, the gate near the drain region is in contact with the gate dielectric layer near the drain region.

In some embodiments, a thickness of the gate near the source region is less than a thickness of the gate near the drain region.

In some embodiments, the manufacturing method further includes forming a high-k gate dielectric layer over the gate dielectric layer before forming the dipole layer, in which after forming the dipole layer, the dipole layer exposes a portion of the high-k gate dielectric layer.

In some embodiments, after forming the source region and the drain region, the gate near the drain region is in contact with the high-k gate dielectric layer near the drain region.

In some embodiments, after forming the source region and the drain region, a sidewall of the dipole layer near the source region is aligned with a sidewall of the high-k gate dielectric layer near the source region.

In some embodiments, after forming the source region and the drain region, the sidewall of the dipole layer near the drain region is aligned with a sidewall of the gate dielectric layer near the drain region.

In some embodiments, after forming the source region and the drain region, the sidewall of the dipole layer near the source region is shifted laterally from a sidewall of the gate dielectric layer near the source region.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIGS. 1-7 illustrate cross section views of a manufacturing method of a semiconductor device in some embodiments of the present disclosure.

FIG. 8 illustrates a semiconductor device in some other embodiments of the present disclosure.

FIG. 9 illustrates a semiconductor device in some other embodiments of the present disclosure.

FIG. 10 illustrates a semiconductor device in some other embodiments of the present disclosure.

### DETAILED DESCRIPTION

Some embodiments of the present disclosure are related an asymmetric metal oxide semiconductor field effect transistor (MOSFET) including a dipole layer. The dipole layer is designed to close to one of the source or the drain of the MOSFET and far away from the other of the source or the drain of the MOSFET. The dipole layer is used to modulate the threshold voltage of the MOSFET and suppress the off-state current to obtain an enhanced on/off ratio of the semiconductor device.

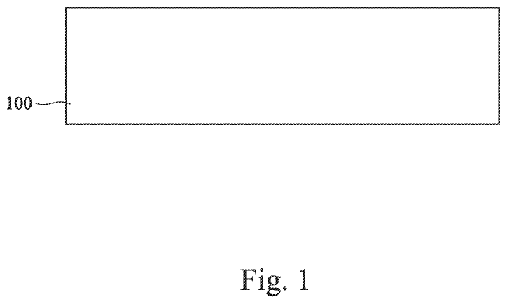

FIGS. 1-7 illustrate cross section views of a manufacturing method of a semiconductor device in some embodiments of the present disclosure. Referring to FIG. 1, a substrate 100 is provided. The substrate 100 is a doped semiconductor substrate. The substrate 100 is a P-type substrate for a NMOS (N-type MOSFET), and the substrate 100 is an N-type substrate for a PMOS (P-type MOSFET). In some embodiments, the substrate 100 may be formed of, for example, silicon, germanium, silicon germanium, silicon carbon, silicon germanium carbon, gallium, gallium arsenic, indium arsenic, indium phosphorus or other IV-IV, III-V or II-VI semiconductor materials.

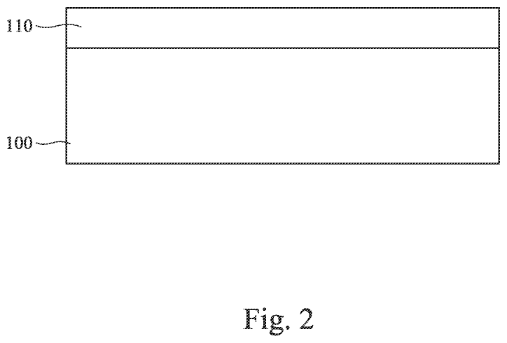

Referring to FIG. 2, a gate dielectric layer 110 is formed over the substrate 100. In some embodiments, the gate dielectric layer 110 is made of silicon oxide.

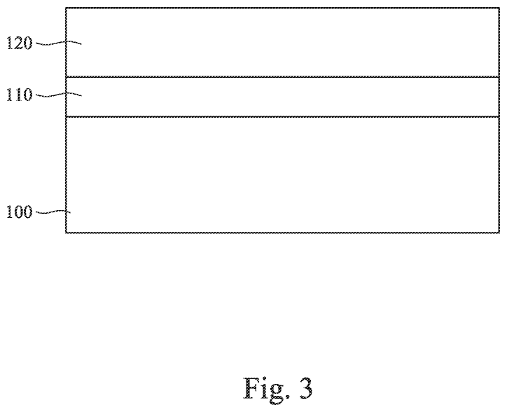

Referring to FIG. 3, a high-k gate dielectric layer 120 is formed over the gate dielectric layer 110, and a dielectric constant of the high-k gate dielectric layer 120 is higher than a dielectric constant of the gate dielectric layer 110. In some embodiments, the high-k gate dielectric layer 120 may be made of hafnium oxide (HfO₂), zirconium oxide (ZrO₂), titanium oxide (TiO₂), alumina (Al₂O₃), oxygen HfSiO, HfSiON, HfTaO, HfTiO, HfZrO or a combination thereof. In some embodiments, the high-k gate dielectric layer 120 may be omitted in the semiconductor device.

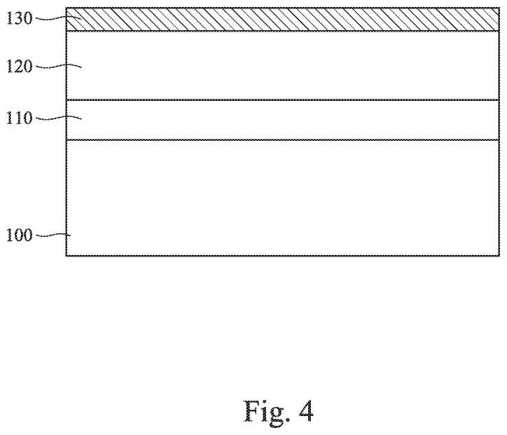

Referring to FIG. 4, a dipole layer 130 is formed over the gate dielectric layer 110 and the high-k gate dielectric layer 120. The dipole layer 130 will be used to modulate the threshold layer of the semiconductor device by oxygen atom exchange between the gate dielectric layer 110 and the dipole layer 130. Therefore, the oxygen concentration of the gate dielectric layer 110 and the oxygen concentration of the dipole layer 130 are different. The material of the dipole layer 130 is different from the material of the high-k gate dielectric layer 120. In some embodiments, the dipole layer 130 is made of Al₂O₃, TiO₂, ZrO₂, MgO, Y₂O₃, Lu₂O₃, La₂O₃ or SrO, or the combinations thereof. In some embodiments, the thickness of the dipole layer 130 is in a range from 1 Å to 50 Å. In some embodiments, the dipole layer 130 may also be made of silicon oxide. The dipole layer 130 and the gate dielectric layer 110 may be formed in the same process chamber by adjusting the proportion of the oxygen of the process gas to form the dipole layer 130 and the gate dielectric layer 110 respectively. Therefore, the oxygen concentration of the dipole layer 130 and the oxygen concentration of the gate dielectric layer 110 are different.

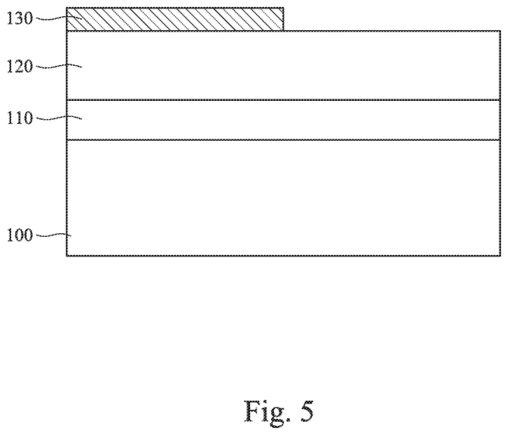

Referring to FIG. 5, the dipole layer 130 is patterned, such that the dipole layer 130 exposes a portion of the high-k gate dielectric layer 120. In some embodiments, the dipole layer 130 is patterned by etching the dipole layer 130 through a hard mask layer over the dipole layer 130 until the high-k gate dielectric layer 120 is exposed.

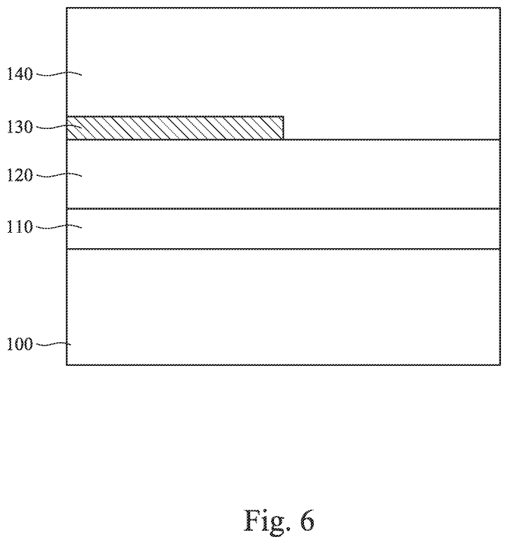

Referring to FIG. 6, a gate 140 is formed over the dipole layer 130, the high-k gate dielectric layer 120 and the gate dielectric layer 110. In some embodiments, the gate 140 may be formed by depositing a conductive material over the dipole layer 130, the high-k gate dielectric layer 120 and the gate dielectric layer 110, and then planarizing the conductive material. Since the dipole layer 130 exposes the high-k gate dielectric layer 120, the high-k gate dielectric layer 120 is in contact with the gate 140 and the dipole layer 130. The thickness of the gate 140 in contact with the high-k gate dielectric layer 120 is greater than the thickness of the gate 140 in contact with the dipole layer 130 after the planarization process. In some other embodiments, the conductive material is not planarized after deposition. Therefore, the gate 140 may have uniform width over the dipole layer 130 and the high-k gate dielectric layer 120.

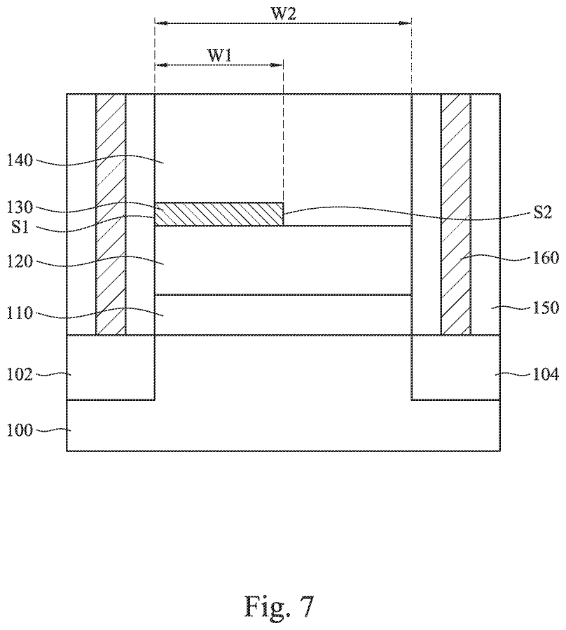

Referring to FIG. 7, the gate dielectric layer 110, the high-k gate dielectric layer 120, the dipole layer 130 and the gate 140 are patterned to expose a portion of the substrate 100. Subsequently, a source region 102 and a drain region 104 are formed in the substrate 100 by using the gate dielectric layer 110, the high-k gate dielectric layer 120, the dipole layer 130 and the gate 140 as mask. The source region 102 and the drain region 104 are at opposite sides of the gate dielectric layer 110. The source region 102 and the drain region 104 are doped regions with conductivity type different from the conductivity type of the substrate 100. The source region 102 and the drain region 104 are N-type doped regions for a NMOS, and the source region 102 and the drain region 104 are P-type doped regions for a PMOS. After the source region 102 and the drain region 104 are formed, the dielectric layer 150 and the contacts 160 are formed over the substrate 100. The dielectric layer 150 separates the gate 140 and the contact 160. One of the sidewall S1 of the dipole layer 130 is in contact with the dielectric layer 150, and the opposite sidewall S2 of the dipole layer 130 is in contact with the gate 140.

The resulting semiconductor device is illustrated in FIG. 7. The semiconductor device includes a substrate 100, a gate dielectric layer 110, a dipole layer 130, a gate 140, a source region 102, a drain region 104, a dielectric layer 150, and contacts 160. The gate dielectric layer 110 is over the substrate 100. The dipole layer 130 is over the gate dielectric layer 110, in which a width W1 of the dipole layer 130 is less than a width W2 of the gate dielectric layer 110. The gate 140 is over the dipole layer 130 and the gate dielectric layer 110. The dielectric layer 150 is over the source region 102 and the drain region 104. The contacts 160 are in the dielectric layer 150, and each of the contacts 160 is over the source region 102 or the drain region 104. The source region 102 and the drain region 104 are at opposite sides of the gate dielectric layer 110. If the semiconductor device is a PMOS, a voltage VDD (which is the highest voltage in the circuit) is applied to the source region 102, and both voltages applied to the gate 140 and the drain region 104 are smaller than the voltage applied to the source region 102 (i.e. V_{GS}<0, and V_{DS}<0). If the semiconductor device is a NMOS, a ground voltage is applied to the source region 102, and both voltages applied to the gate 140 and the drain region 104 are greater than the voltage applied to the source region 102 (i.e. V_{GS}>0, and V_{DS}>0).

The semiconductor device is an asymmetric structure, since the dipole layer 130 is close to the source region 102 rather than the drain region 104. Specifically, the sidewall of the dipole layer 130 near the source region 102 is aligned with a sidewall of the gate dielectric layer 110 near the source region, and a sidewall of the dipole layer 130 near the drain region 104 is shifted laterally from a sidewall of the gate dielectric layer 110 near the drain region 104. A thickness of the gate 140 near the source region 102 is less than a thickness of the gate 140 near the drain region 104. The dipole layer 130 is used to decrease the threshold voltage of the semiconductor device to increase inversion charge density. Inversion charge density is the charge density of an inversion layer in the substrate 100 under the gate 140, and increasing inversion charge density can increase saturation current of the semiconductor device. Decreasing the threshold voltage of the semiconductor device can be achieved by the oxygen atom exchange between the gate dielectric layer 110 and the dipole layer 130 near the source region 102. The thickness of the inversion layer increases if the dipole layer 130 near the source region 102 is provided with following oxygen concentration, which leads to greater saturation current of the semiconductor devices. In some embodiments, when the dipole layer 130 is near the source region 102, the oxygen concentration of the dipole layer 130 is lower than the oxygen concentration of the gate dielectric layer 110 for NMOS, and the oxygen concentration of the dipole layer 130 is higher than the oxygen concentration of the gate dielectric layer 110 for PMOS. The dipole layer 130 near the drain region 104 is removed, and thus oxygen atom exchange does not occur near the drain region 104 and thereby suppress the off-state current.

The semiconductor device further includes a high-k gate dielectric layer 120 between the gate dielectric layer 110 and the dipole layer 130, in which a dielectric constant of the high-k gate dielectric layer 120 is higher than a dielectric constant of the gate dielectric layer 110. The high-k gate dielectric layer 120 is in contact with the gate. The width W1 of the dipole layer 130 is less than a width W2 of the high-k gate dielectric layer 120. The sidewall of the dipole layer 130 near the source region 102 is aligned with a sidewall of the high-k gate dielectric layer 120 near the source region 102. The sidewall of the dipole layer 130 near the drain region 104 is shifted laterally from a sidewall of the high-k gate dielectric layer 120 near the drain region 104. The gate 140 near the drain region 104 is in contact with the high-k gate dielectric layer 120 near the drain region 104.

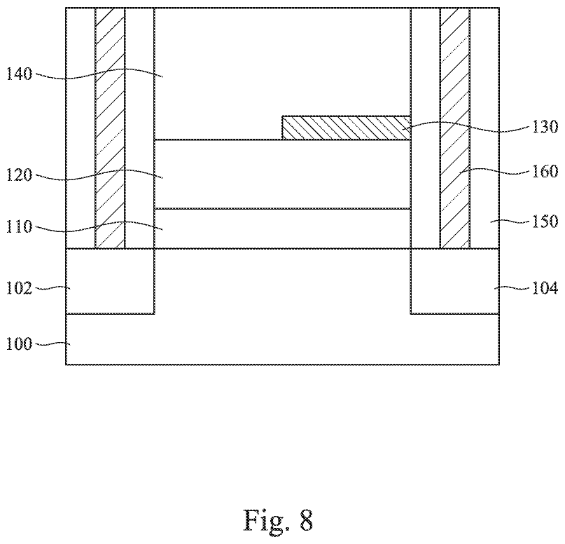

FIG. 8 illustrates a semiconductor device in some other embodiments of the present disclosure. The semiconductor device in FIG. 8 is similar to the semiconductor device in FIG. 7. The difference is that the dipole layer 130 in FIG. 8 is near the drain region 104 rather than the source region 102. The sidewall of the dipole layer 130 near the drain region 104 is aligned with a sidewall of the gate dielectric layer 110 near the drain region 104. The sidewall of the dipole layer 130 near the source region 102 is shifted laterally from a sidewall of the gate dielectric layer 110 near the source region 102. The gate 140 near the source region 102 is in contact with the high-k gate dielectric layer 120 near the source region 102. The thickness of the gate 140 near the drain region 104 is less than the thickness of the gate 140 near the source region 102. The dipole layer 130 is used to increase the threshold voltage of the semiconductor device to decrease inversion charge density. Increasing the threshold voltage of the semiconductor device can be achieved by the oxygen atom exchange between the gate dielectric layer 110 and the dipole layer 130 near the drain region 104. The thickness of the inversion layer decreases if the dipole layer 130 near the drain region 104 is provided with following oxygen concentration, which leads to lower saturation current of the semiconductor devices. In some embodiments, when the dipole layer 130 is near the drain region 104, the oxygen concentration of the dipole layer 130 is higher than the oxygen concentration of the gate dielectric layer 110 for NMOS, and the oxygen concentration of the dipole layer 130 is lower than the oxygen concentration of the gate dielectric layer 110 for PMOS. The dipole layer 130 near the source region 102 is removed, and thus oxygen atom exchange does not occur near the source region 102 and thereby maintain the on-state current. Therefore, it also leads to the enhanced on/off ratio of the semiconductor device.

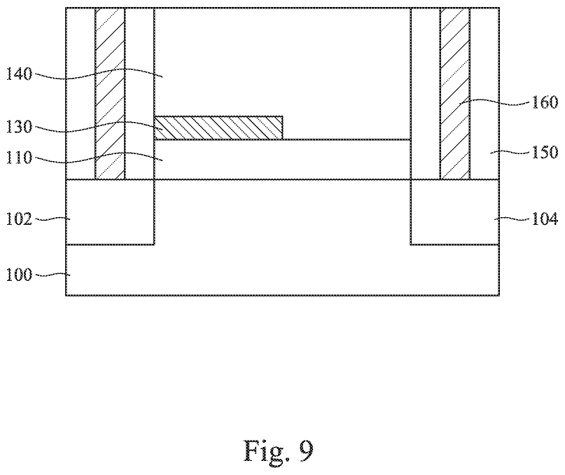

FIG. 9 illustrates a semiconductor device in some other embodiments of the present disclosure. The semiconductor device in FIG. 9 is similar to the semiconductor device in FIG. 7. The difference is that the high-k gate dielectric layer 120 is not provided in the semiconductor device in FIG. 9. The dipole layer 130 is in contact with the gate dielectric layer 110, and the gate 140 near the drain region 104 is also in contact with the gate dielectric layer 110.

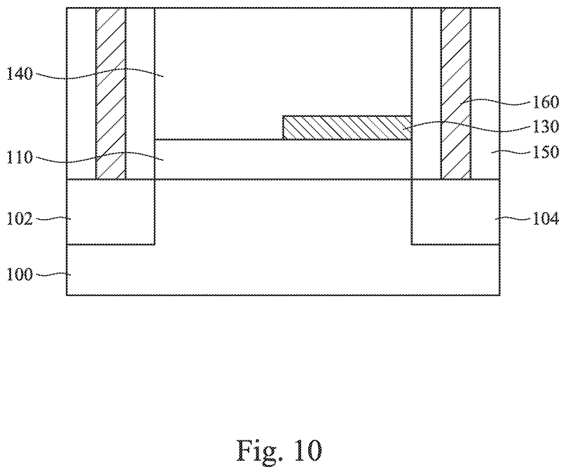

FIG. 10 illustrates a semiconductor device in some other embodiments of the present disclosure. The semiconductor device in FIG. 10 is similar to the semiconductor device in FIG. 8. The difference is that the high-k gate dielectric layer 120 is not provided in the semiconductor device in FIG. 10. The dipole layer 130 is in contact with the gate dielectric layer 110, and the gate 140 near the source region 102 is also in contact with the gate dielectric layer 110.

As mentioned above, the semiconductor device in some embodiments of the present disclosure includes a dipole layer to modulate the threshold voltage and suppress the off-state current of the semiconductor device at the same time. The width of the dipole layer is less than the width of the gate dielectric layer, and the location of the dipole layer may modulate the threshold voltage of the semiconductor device. For example, the dipole layer can be used to decrease the threshold voltage if the dipole layer is near the source region, and the dipole layer can be used to increase the threshold voltage if the dipole layer is near the drain region. The other side of the dipole layer is removed to suppress the off-state current or maintain the on-state current. Therefore, the on/off ratio of the semiconductor device can be enhanced.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor device, comprising:
a substrate;
a gate dielectric layer over the substrate;
a dipole layer over the gate dielectric layer, wherein the dipole layer is an oxygen-containing layer, and a width of the dipole layer is less than a width of the gate dielectric layer;
a gate over the dipole layer and the gate dielectric layer;
a source region in the substrate; and
a drain region in the substrate, wherein the source region and the drain region are at opposite sides of the gate dielectric layer.

2. The semiconductor device of claim 1, wherein a sidewall of the dipole layer near the source region is aligned with a sidewall of the gate dielectric layer near the source region.

3. The semiconductor device of claim 1, wherein a sidewall of the dipole layer near the drain region is shifted laterally from a sidewall of the gate dielectric layer near the drain region.

4. The semiconductor device of claim 1, further comprising:
a high-k gate dielectric layer between the gate dielectric layer and the dipole layer, wherein a dielectric constant of the high-k gate dielectric layer is higher than a dielectric constant of the gate dielectric layer.

5. The semiconductor device of claim 4, wherein the high-k gate dielectric layer is in contact with the gate.

6. The semiconductor device of claim 4, wherein the width of the dipole layer is less than a width of the high-k gate dielectric layer.

7. The semiconductor device of claim 4, wherein a sidewall of the dipole layer near the source region is aligned with a sidewall of the high-k gate dielectric layer near the source region.

8. The semiconductor device of claim 4, wherein a sidewall of the dipole layer near the drain region is shifted laterally from a sidewall of the high-k gate dielectric layer near the drain region.

9. The semiconductor device of claim 1, wherein a sidewall of the dipole layer near the drain region is aligned with a sidewall of the gate dielectric layer near the drain region.

10. The semiconductor device of claim 1, wherein a sidewall of the dipole layer near the source region is shifted laterally from a sidewall of the gate dielectric layer near the source region.

11. A manufacturing method of a semiconductor device, comprising:
forming a gate dielectric layer over a substrate;
forming a dipole layer over the gate dielectric layer, wherein the dipole layer covers a portion of the gate dielectric layer;
forming a gate over the dipole layer and the gate dielectric layer; and
forming a source region and a drain region in the substrate, wherein the source region and the drain region are at opposite sides of the gate dielectric layer.

12. The manufacturing method of claim 11, wherein after forming the source region and the drain region, a sidewall of the dipole layer near the source region is aligned with a sidewall of the gate dielectric layer near the source region.

13. The manufacturing method of claim 11, wherein after forming the source region and the drain region, a sidewall of the dipole layer near the drain region is shifted laterally from a sidewall of the gate dielectric layer near the drain region.

14. The manufacturing method of claim 11, wherein after forming the source region and the drain region, the gate near the drain region is in contact with the gate dielectric layer near the drain region.

15. The manufacturing method of claim 11, wherein a thickness of the gate near the source region is less than a thickness of the gate near the drain region.

16. The manufacturing method of claim 11, further comprising:
forming a high-k gate dielectric layer over the gate dielectric layer before forming the dipole layer, wherein after forming the dipole layer, the dipole layer exposes a portion of the high-k gate dielectric layer.

17. The manufacturing method of claim 16, wherein after forming the source region and the drain region, the gate near the drain region is in contact with the high-k gate dielectric layer near the drain region.

18. The manufacturing method of claim 16, wherein after forming the source region and the drain region, a sidewall of the dipole layer near the source region is aligned with a sidewall of the high-k gate dielectric layer near the source region.

19. The manufacturing method of claim 11, wherein after forming the source region and the drain region, a sidewall of the dipole layer near the drain region is aligned with a sidewall of the gate dielectric layer near the drain region.

20. The manufacturing method of claim 11, wherein after forming the source region and the drain region, a sidewall of the dipole layer near the source region is shifted laterally from a sidewall of the gate dielectric layer near the source region.
